(19) United States
(12) Patent Application Publication
(10) Pub. No.: US 2011/0317373 A1
(43) Pub. Date: Dec. 29, 2011

(54) Method and Apparatus for Interconnecting Circuit Boards

(76) Inventor: William James McDermid, Longmont, CO (US)

(21) Appl. No.: 13/166,814

(22) Filed: Jun. 23, 2011

Related U.S. Application Data
(60) Provisional application No. 61/357,910, filed on Jun. 23, 2010.

(51) Int. Cl. H05K 1/14; H05K 3/30

(52) U.S. Cl. 361/730; 361/736; 29/832

(57) ABSTRACT

A method and apparatus are provided for the interconnection of multiple circuit boards within a device. A module is provided which comprises multiple circuit boards interconnected with a plurality of connectors. Modules may be interconnected to other modules using the same connectors. Circuit components are disposed on inner surfaces of the circuit boards of the module. Multiple circuit boards and modules are interconnected by contacts that do not require soldering, that permit the circuit boards and modules to be removably coupled to each other by the contacts, and that permit circuit boards to be positioned by a spaced amount that results in a small spacing between circuit boards. Enclosures are also provided, which allow modules to be configured and secured in both a horizontal and vertical direction. Thus, modules may be interconnected to other modules on each side, as well as interconnected to other modules stacked above or below the module.

### BACKGROUND OF THE INVENTION

1. Field of the Invention

This invention relates to a method and apparatus for interconnecting circuit boards and, in particular, to circuit boards adapted to be housed within an enclosure. This invention further relates to a method and apparatus for interconnecting circuit boards of different modules, wherein a module comprises two circuit boards.

2. Statement of the Problem

Circuit boards are widely used in electronic devices and systems. It is commonplace to use a plurality of circuit boards in a television, a laptop computer, a mobile telephone, an MP3 player, a digital voice recorder, etc. In general, the more complex the device, the greater number of circuit boards that are required for the device.

It is a problem in the industry to use multiple boards within a device because of problems related to efficiently and economically mounting and interconnecting the multiple boards to each other. Industry standard specification PC 104 characterizes the recommended specifics of stacking or mounting a plurality of circuit boards vertically. This standard specifies that vertically stacked circuit boards must have a ½″ space between them. The component's are mounted on only one side of the circuit board and are contained within this ½″ spacing. This ½″ spacing increases the overall size of the device containing the stacked circuit boards. Thus, a device containing four circuit boards would have a height of 2″; a device with six circuit boards would have a height of 3″, etc. Compliance with this standard precludes such devices from being used in laptops, mobile telephones and other devices that must be thin to be commercially attractive.

The PCI standard characterizes the requirements for devices containing a motherboard or backplane. The requirements include having a plurality of the circuit boards spaced at least ½″ from each other, connecting the circuit boards at right angles to the motherboard or backplane. Compliance with this standard precludes the use of the circuit boards and the motherboard in devices such as cell phones of a like where the devices must be thin in order to be commercially acceptable.

In accordance with the PC 104 and PCI standards, electronic elements such as resistors, capacitors, coils, transformers, etc. are positioned on only one side of the board in the ½″ spacing between circuit boards. When the components are of a heat generating type, it is difficult to mount the components in this ½″ spacing because of thermal problems created by the generated heat. This in turn, may require the use of fans and the like to maintain a satisfactory temperature of the circuit boards and its components. Further, the use of motherboards connected to multiple circuit boards presents a problem protecting the boards from vibrations.

It can be seen that prior art arrangements having multiple circuit boards creates problems that preclude their use in miniaturized devices. These problems include space, thermal, and vibration problems.

### SUMMARY OF THE SOLUTION

The present invention solves the above and other problems by the provision of a method and apparatus that provides for the interconnection of multiple modules and circuit boards within a device. In accordance with the invention, a module is provided which comprises multiple circuit boards interconnected with a plurality of connectors. Further, a pair of circuit boards, herein referred to as a module, may also be interconnected to other like modules. The multiple circuit boards and modules are interconnected by contacts that permit the circuit boards and modules to be removably coupled to each other, and that permit circuit boards to be positioned by a spaced amount that results in a small spacing between circuit boards. This small spacing facilitates the use of modules in miniaturized devices where small dimensions are a prerequisite to commercial success of the devices. The use of the method and apparatus of the present invention permits the use of the modules in mobile telephones, laptop computers, MP3 players, digital voice recorders, etc., where space is at a premium. This enables devices housing the circuit boards to be commercially attractive by permitting the device to have increased functionality without an increase in size.

The method and apparatus of the present invention also permits the removal and insertion of modules. This permits a module to be removed for maintenance and then repaired or replaced by another module. This is particularly advantageous since it permits a working device to be easily repaired instead of being discarded since it is often not feasible to repair a single motherboard and/or a plurality of a circuit boards interconnected by wires and the like.

The ability of the modules to be removed is advantageous since it permits modules to be used for different applications by inserting a combination of modules into the device to create a device having a required functionality. This feature allows a manufacturer to store generic modules that can be stored and later converted into a device having a specific functionality by the insertion of a specific combination of modules. This feature permits a manufacturer or assembler to store a fewer number of parts that can be converted to a specific use using different types of circuit boards and modules.

The method and apparatus of the present invention is further advantageous in that it provides increased thermal capabilities for the module in which it is used. This is achieved by thermally coupling components to the faces of a module, with the face being in contact with surreally conductive material that dissipates heat by conduction rather than by thermal convection requiring airflow. This permits a device to use modules of smaller size since space does not have to be provided within the device to accommodate airflow or the like.

The method and apparatus of the present invention is ubiquitous in that the modules are equipped with contacts along the perimeter of their top and bottom faces. This permits modules to be placed side-by-side or stacked vertically. When the modules are vertically positioned, they are interconnected to each other by engaging the perimeter contacts of stacked modules to each other. These perimeter contacts also permit modules to be horizontally positioned in the same plane and connected to each other by a thin connector sheet that enables a module to be connected to an adjacent module by pressing the connector sheet down so that its contacts interconnect the perimeter contacts of the adjacent modules.

The contacts may be on one or all of the perimeters of the module. This provides great flexibility in the assembly of a device using a plurality of modules with different functionality. For example, a device can be equipped with a single pair of circuit boards (i.e., a module). Also, a device can have modules positioned in a plane and connected to each other by their perimeter contacts. A device may also have modules vertically stacked atop each other. Further, a device may have any number of horizontally interconnected modules as well as any number of vertically stacked modules.

The space between the upper and lower circuit boards of a module is used to mount components on one side of each circuit board. The components may be controllably positioned on the surface of the lower and upper circuit boards of the module. The components on the upper or lower circuit boards of a module may be positioned so that a tall element on one of the circuit boards does not abut a tall element on the other circuit board. In other words, a tall element on a lower circuit board may be positioned vertically opposite a smaller element on the upper circuit board, or vice versa. The capability of positioning the elements in this manner permits a smaller spacing between two vertical circuit boards of a module, since the component's on adjacent vertical circuit boards are controllably positioned to fill the space available between the two circuit boards.

In use, modules may be stacked vertically and mounted within an enclosure so that the lower surface of the bottom circuit board of the module abuts the lower surface of the enclosure. The top surface of the top circuit board of the module engages the bottom surface of the upper wall of the enclosure. This provides for increased thermal capabilities as above discussed.

The invention may include other exemplary embodiments described below.

### DESCRIPTION OF THE DRAWINGS

The above and other advantages and features of the invention may be better understood from a reading of the detailed description taken in conjunction with the drawings. The same reference number represents the same element on all drawings.

FIG. 1 is an exploded top isometric view of a module in an exemplary embodiment of the invention.

FIG. 2 is an exploded bottom isometric view of a module in an exemplary embodiment of the invention.

FIG. 3 is an isometric view of a module in an exemplary embodiment of the invention.

FIG. 4 is an exploded top isometric view of a 3×2 enclosure adapted to house a plurality of modules in an exemplary embodiment of the invention.

FIG. 5 is an exploded bottom isometric view of a 3×2 enclosure adapted to house a plurality of modules in an exemplary embodiment of the invention.

FIG. 6 is a top view of a 3×3 enclosure adapted to house a plurality of modules in an exemplary embodiment of the invention.

FIG. 7 is an exploded isometric view of a multi-layered enclosure adapted to house a plurality of layers of modules in an exemplary embodiment of the invention.

FIG. 8 is a side view of the connection between the two circuit boards of a module in an exemplary embodiment of the invention.

FIG. 9 is a side view of two modules matingly engaged in a stacked configuration in an exemplary embodiment of the invention.

FIG. 10 is a side view of two modules matingly engaged in a side-by-side configuration in an exemplary embodiment of the invention.

FIG. 11 is an isometric view of a row of inside contacts in an exemplary embodiment of the invention.

FIG. 12 is an isometric view of a row of outside contacts in an exemplary embodiment of the invention.

FIG. 13 is an isometric view of insulator material separating the top outside contacts, the bottom outside contacts, and the inside contacts in an exemplary embodiment of the invention.

FIG. 14 is an isometric view of an apparatus adapted to connect a module to an external device in an exemplary embodiment of the invention.

FIG. 15 is a flow chart of a method for forming a module in an exemplary embodiment of the invention.

### ASPECTS

An aspect of the invention comprises a system, the system including at least one module. The module comprises a first circuit board having a component surface; a second circuit board having a component surface, the component surface of the second circuit board disposed facing the component surface of the first circuit board; and an apparatus adapted to physically and electrically couple the first circuit board and the second circuit board, and further adapted to matingly engage the module with a second module.

Preferably, the apparatus for physically and electrically coupling the first circuit board and second circuit board comprises: a plurality of outside spring leaf contacts that clamp the outer sides of the first and second circuit boards along each edge of the first and second circuit boards to keep the first and second circuit boards from moving apart, each outside spring leaf contact extending beyond the outer faces of the first and second circuit boards and adapted to matingly engage contact pads on the outer faces of the module with the second module; and a plurality of inside spring leaf contacts pressed between the component sides of the first and second circuit boards along each edge of the first and second circuit boards to keep the first and second circuit boards from moving together, each inside spring leaf contact adapted to matingly engage with contact pads on the component sides of the first and second circuit boards to electronically couple the first circuit board and the second circuit board.

Preferably, the apparatus for physically and electrically coupling the first circuit board and second circuit board further comprises: insulator material substantially a same length as an edge of the module, the insulator material having a plurality of slots adapted to electrically isolate each pair of matingly engaged outside spring leaf contacts and inside spring leaf contacts from other pairs of matingly engaged outside spring leaf contacts and inside spring leaf contacts.

Preferably, the plurality of outside spring leaf contacts further comprises: at least one power contact; at least one ground contact; at least one control signal contact; and at least one data signal contact.

Preferably, the system comprises a plurality of modules.

Preferably, sizes of each edge of the first circuit board and the second circuit board are integer multiples of a base value.

Preferably, the first circuit board and the second circuit board further comprise means for securing the module in place in an enclosure housing the module.

Preferably, the module comprises: a cut-out on each of the four corners of the first circuit board, and a cut-out on each of the four corners of the second circuit board, the cut-outs on the first circuit board and the cut-outs on the second circuit board adapted to pass through a spacer in the enclosure housing the module to secure the module in place around the spacer.

Preferably, the enclosure comprises a plurality of spacers arranged in a grid pattern, each spacer being equally spaced apart in an X-direction and a Y-direction of the enclosure, with the base value equal to a distance between centers of two of the plurality of spacers.

Another aspect of the invention is a system comprising: a plurality of modules, each module comprising: a first circuit board having a component surface; and a second circuit board having a component surface, the component surface of the second circuit board disposed facing the component surface of the first circuit board; and an apparatus adapted to physically and electrically couple the first circuit board and the second circuit board and adapted to matingly engage the module with at least one of the other plurality of modules, and the system further comprising an enclosure adapted to house the plurality of modules; and a plurality of spacers coupled to the enclosure, the plurality of spacers arranged in a grid pattern, each spacer being equally spaced apart in an X-direction and a Y-direction of the grid pattern, wherein sizes of each edge of the first circuit board and the second circuit board of each module are integer multiples of a base value, the base value equal to a distance between centers of two of the plurality of spacers.

Preferably, the apparatus for physically and electrically coupling the first circuit board and second circuit board comprises: a plurality of outside spring leaf contacts that clamp the outer sides of the first and second circuit boards along each edge of the first and second circuit boards to keep the first and second circuit boards from moving apart, each outside spring leaf contact extending beyond the outer faces of the first and second circuit boards and adapted to matingly engage contact pads on the outer faces of the module with the second module; and a plurality of inside spring leaf contacts pressed between the component sides of the first and second circuit boards along each edge of the first and second circuit boards to keep the first and second circuit boards from moving together, each inside spring leaf contact adapted to matingly engage with contact pads on the component sides of the first and second circuit boards to electronically couple the first circuit board and the second circuit board.

Preferably, the system comprises a plurality of layers of modules housed in the enclosure, wherein at least one layer of modules is stacked atop a lower layer of modules.

Preferably, the plurality of layers of modules are electronically coupled together by the outside spring leaf contacts, the outside spring leaf contacts electrically coupling a first module on a first layer and a second module on a second layer, the second module stacked atop the first module.

Preferably, the system comprises an apparatus adapted to electrically couple at least one of the plurality of modules with an external device, the apparatus comprising: a cable electrically coupled to the apparatus module, the cable adapted to electrically couple the apparatus module with the external device.

Another aspect of the invention are modules with footprints that are restricted to closed shapes that can be constructed by arranging segments of a unit length end-to-end such that all segments are either parallel or perpendicular to one-another and where said modules have a plurality of electrical contacts centered along the edge of at least one of said segments and extending above and below the edge such that a plurality of modules can be electrically connected to one-another by way of said contacts when said plurality of modules are stacked atop one-another.

Preferably, the modules are also arranged side-by-side in a plane and connected by an apparatus that contains conductive strips where said apparatus is oriented parallel to said modules in order to mate with said perimeter contacts of both modules in order to effect electrical connection between the contacts of said modules.

Another aspect of the invention is a method for forming a module, the method comprising: providing a first circuit board having a component surface; providing a second circuit board having a component surface, the component surface of the second circuit board disposed facing the component surface of the first circuit board; and positioning components on the component surface of the first circuit board and the component surface of the second circuit board to minimize un-utilized space between the first circuit board and the second circuit board.

Preferably, there is a first height between the first circuit board and the second circuit board, and positioning components further comprises: positioning a first component on the component surface of the first circuit board, the first component having a second height less than the first height; determining a remaining height based on the first height minus the second height; and positioning a second component on the component surface of the second circuit board, the second component having a third height which is less than or equal to the remaining height.

### DETAILED DESCRIPTION OF THE INVENTION

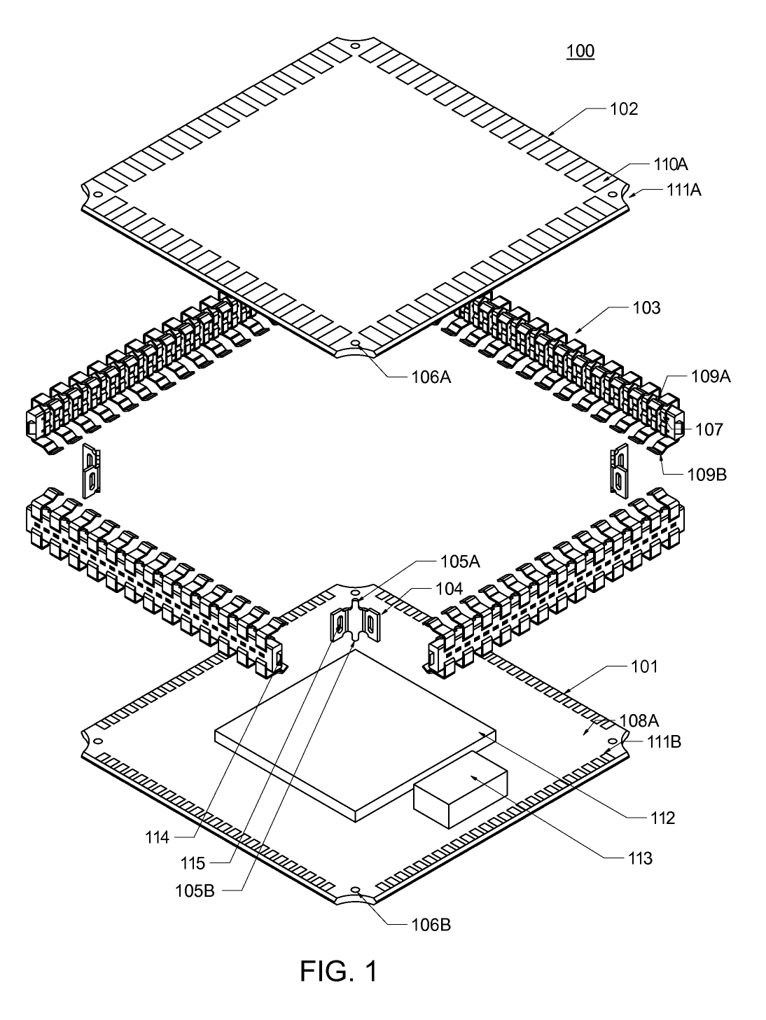

FIGS. 1-15 and the following description depict specific exemplary embodiments of the invention to teach those skilled in the art how to make and use the best mode of the invention. For the purpose of teaching inventive principles, some conventional aspects of the invention have been simplified or omitted. Those skilled in the art will appreciate variations from these embodiments that fall within the scope of the invention. Those skilled in the art will appreciate that the features described below can be combined in various ways to form multiple variations of the invention. As a result, the invention is not limited to the specific embodiments described below, but only by the claims and their equivalents.

FIG. 1 is an exploded isometric view of a module 100 in an exemplary embodiment of the invention. FIG. 1 illustrates an internal view of the bottom of module 100. Module 100 includes a bottom circuit board 101 and a top circuit board 102. Top circuit board 102 has a component surface (not visible in FIG. 1) which is disposed facing a component surface of bottom circuit board 102. The component surface of bottom circuit board 102 contains components 112 and 113 of differing heights. The terms top and bottom are used for illustrative purposes only. Module 100 may be oriented in any number of directions such that bottom circuit board 101 and top circuit board 102 may be disposed in opposite positions, or may comprise opposite sides of module 100. Module 100 includes a connector 103 adapted to physically and electrically couple bottom circuit board 101 and top circuit board 102. To electrically couple bottom circuit board 101 and top circuit board 102, the connector 103 comprises a plurality of inside contacts 107 that engage inside contact pads 108A on circuit board 102 with contact pads 108B (not visible in FIG. 1) on circuit board 101. The engagement of bottom inside contact pads 108B and top inside contact pads 108A will be subsequently described. As illustrated in FIG. 1, there are twenty-five pairs of bottom inside contacts 108B and top inside contacts 108A along each edge of module 100. However, any number of pairs of bottom inside contacts 108B and top inside contacts 108A may be disposed along each edge of module 100 depending on desired design criteria.

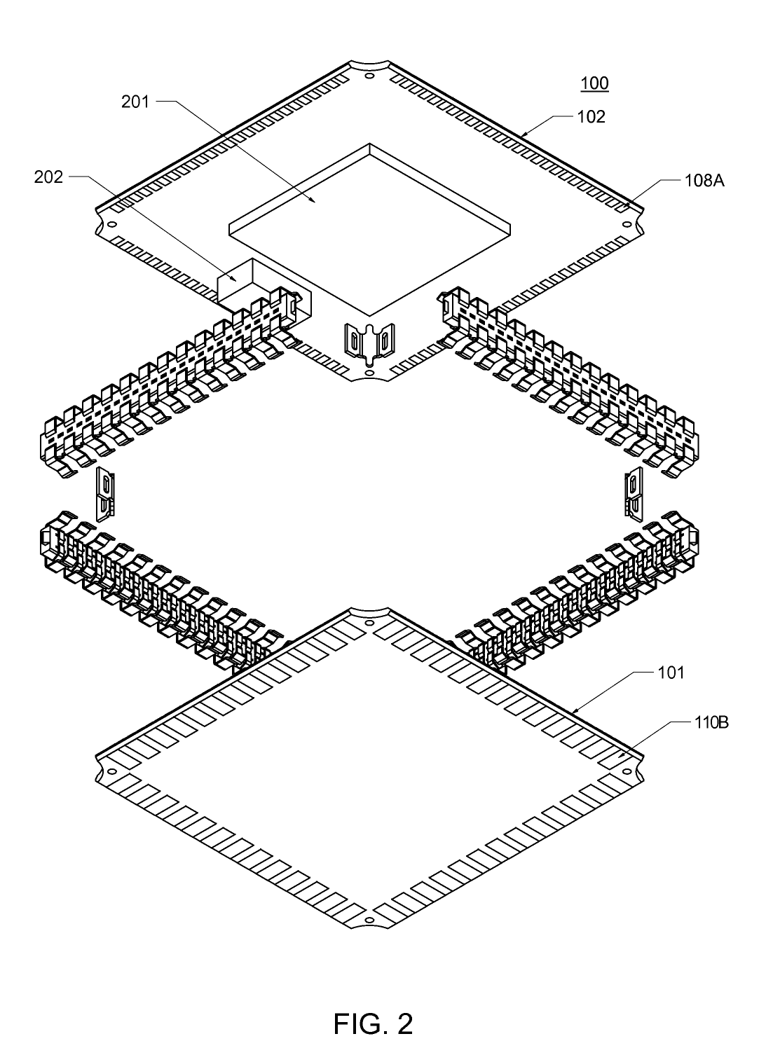

The coupling apparatus of module 100 may further include a plurality of outside contacts 109A and 109B adapted to matingly engage module 100 with another like module (not shown) to electrically couple the two modules. A portion of outside contacts 109B and 109A are electrically coupled to bottom outside contact pads 110B (not visible in FIG. 2) of circuit board 101 and outside contact pads 110A of circuit board 102 respectively to electrically couple bottom circuit board 101 and top circuit board 102 with other modules. As illustrated in FIG. 1, there are thirteen outside contacts 109A on the top and thirteen outside contacts on the bottom along each edge of module 100. Thus, thirteen top outside contacts 109A may be electrically coupled to another module on each side of module 100 and thirteen bottom outside contacts 109B may be electrically coupled to another module on each side of module 100. Module 100 as illustrated may be electrically coupled to eight other modules, two on each side of module 100.

Corner clips 104 are captured between circuit boards 101 and 102 when corner clip posts 105A and 105B pass through holes 106A and 106B respectively in circuit boards 102 and 101 respectively. Said corner clips hold connectors 103 to module 100 by way of tab 114 of connector 103 snapping into slot 115 of corner clip 104.

Bottom circuit board 101 includes a plurality of cut-outs 111B on each corner of bottom circuit board 101. Top circuit board 102 includes a corresponding plurality of cut-outs 111A on each corner of top circuit board 102. The cut-outs 111A and 111B are adapted to secure module 100 in place in an enclosure (not shown in FIG. 1). The enclosure and securing of module 100 within the enclosure will be subsequently described.

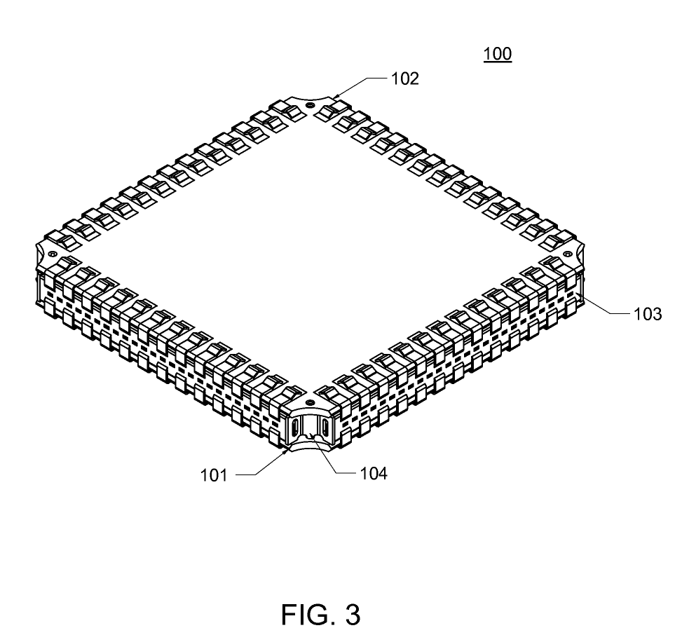

FIG. 3 is an isometric view of module 100 in an exemplary embodiment of the invention. More specifically, FIG. 3 illustrates the final assembly of module 100 after bottom circuit board 101 and top circuit board 102 are physically and electrically coupled by connectors 103 and corner clips 104. While module 100 is illustrated as a square, module 100 may be other types of parallelepipeds, such as a rectangle.

To minimize a height of module 100, components may be disposed on the inside surfaces of both bottom circuit board 101 and top circuit board 102. Preferably, components disposed on bottom circuit board 101 and top circuit board 102 are staggered to avoid having two large components on corresponding locations of bottom circuit board 101 and top circuit board 102. If one tall component 113 is disposed on bottom circuit board 101, and a second tall component is disposed on top circuit board 102 immediately above the tall component on bottom circuit board 101, then the height of module 100 may become larger than necessary. Thus, it may be beneficial to place a tall component 113 on bottom circuit board 101, and place a short component in the corresponding location on top circuit board 102 above the tall component. Likewise, a tall component may be placed on top circuit board 102, and a short component may be placed on bottom circuit board 101 below the tall component on top circuit board 102. Further, if a relatively tall component is placed on either bottom circuit board 101 or top circuit board 102, then the corresponding location on the other circuit board may be left empty to minimize the overall height of module 100. This staggering of components is advantageous, because a minimum height of the module is kept as small as physically possible depending on the largest component that may be disposed on bottom circuit board 101 or top circuit board 102.

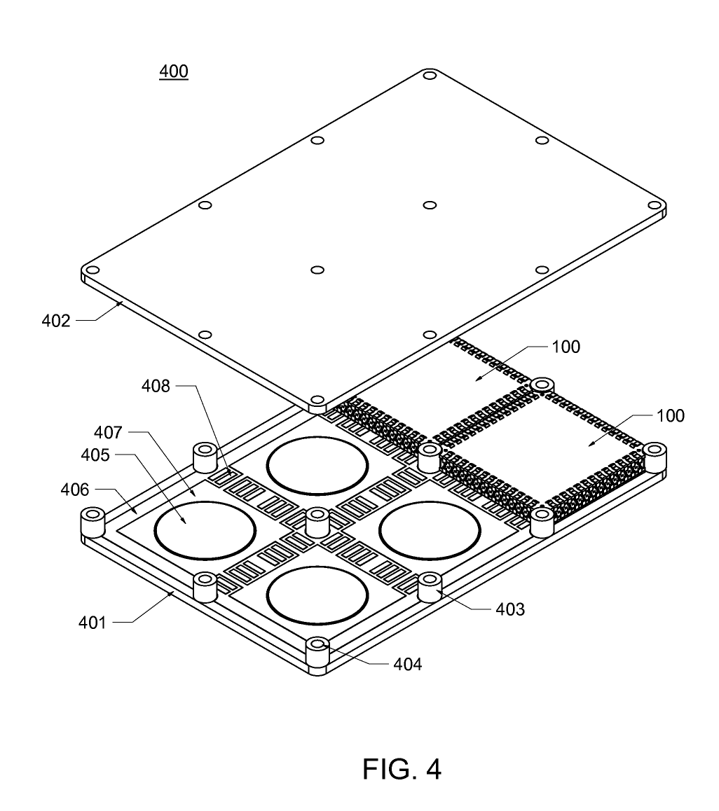

FIG. 4 is an isometric view of a 3×2 enclosure 400 adapted to house a plurality of modules 100 in an exemplary embodiment of the invention. Enclosure 400 comprises a bottom plate 401 and a plurality of spacers 403. More specifically, enclosure 400 comprises twelve spacers 403. Spacers 403 are arranged in a grid pattern, with each spacer 403 being equally spaced apart in an X-direction and a Y-direction of the grid pattern. Each module 100 has corresponding cut-outs 111 to fit within spacers 403. Further, the size of each edge of bottom circuit board 101 and top circuit board 102 may be integer multiples of a base value. The base value is equal to a distance between the centers of two of the spacers 403. Thus, modules 100 may be placed at any location of enclosure 400 and fit within any four spacers 403. Connector strips 408 on circuit substrate 406 electrically couple adjacent modules 100. Circuit plane 407 on circuit substrate 406 distributes ground to modules 100. Thermal contact pad 405 passes through circuit substrate 406 to thermally couple bottom plate 401 to modules 100. Holes 404 in spaces 403 accommodate fasteners (not shown) to affix top plate 402 to bottom plate 401 and to compress modules 100 with connector strips 408 and ground plane 407. Enclosure 400 is adapted to house a total of six square modules 100.

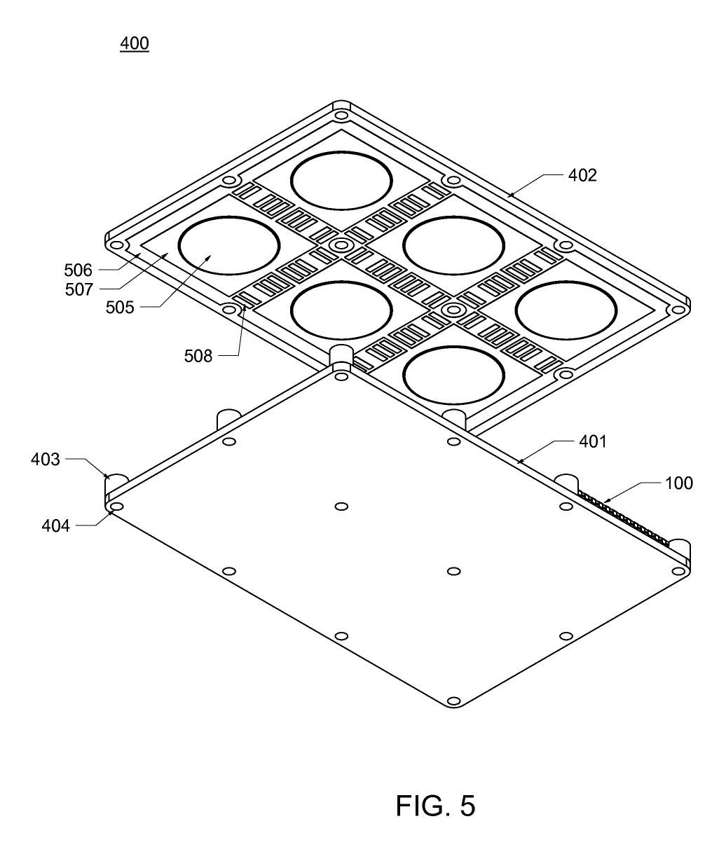

FIG. 5 is an isometric view of a 3×2 enclosure 400 showing the inside surface of top plate 402 and circuit substrate 506. Connector strips 508 on circuit substrate 506 electrically couple adjacent modules 100. Circuit plane 507 on circuit substrate 506 distributes power to modules 100. Thermal contact pad 505 passes through circuit substrate 506 to thermally couple top plate 501 to modules 100.

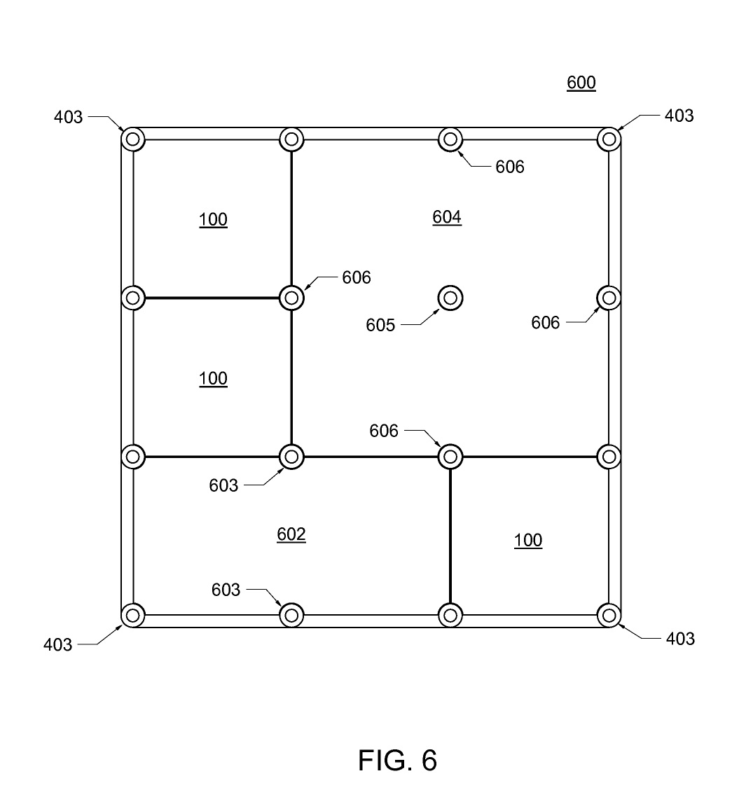

FIG. 6 is a top view of a 3×3 enclosure 600 adapted to house a plurality of modules 100 in an exemplary embodiment of the invention. As illustrated, enclosure 600 includes sixteen spacers 403, and is adapted to house nine square modules 100. However, if each edge of a module 100 is an integer multiple of a base value, modules do not need to be square shaped, but rather, may be any type of parallelepiped, or could even be other shapes, such as L-shaped or U-shaped. For example, an L-shaped module may comprise three or more 1×1 modules, and a U-shaped module may comprise five or more 1×1 modules. Exemplary dimensions of a 1×1 square module 100 are 25.6 mm×25.6 mm, with a height of 3.2 mm. Exemplary dimensions of cut-outs 111A and 111B of a 1×1 square module 100 have a 2 mm radius. Thus, a spacer 403 may have a 4 mm diameter to secure up to four 1×1 modules in place.

As illustrated in FIG. 6, module 602 is a 1×2 module (e.g., is twice the length of module 100, but the same width as module 100). Thus, module 602 may be 25.6 mm by 51.2 mm. Module 602 includes six cut-outs, one on each corner of module 602, and two cut-outs 603 in the middle along the longest edge of module 602.

Module 604 is a 2×2 module (e.g., is twice the length and twice the width of module 100). Thus, module 604 may be 51.2 mm by 51.2 mm. Module 604 includes nine cut-outs, four on each corner of module 604, one cut-out 605 in the center of module 604, and one cut-out 606 in the middle of each side of module 604.

Spacers 403 have been described as arranged in a grid pattern, where each spacer 403 is spaced equally apart from other spacers 403 in both an X-direction and a Y-direction of the grid pattern. However, design criteria may dictate that some spacers 403 are not needed in the grid pattern. For example, a space in an enclosure may be selected to hold a module which is larger than a 1×1 module. Therefore, in some embodiments, a portion of the spacers 403 may be omitted from the grid pattern. For example, two adjoining spacers 403 may be placed two base value units of length apart, while other spacers 403 are placed one base value unit of length apart. This permits the utilization of the standard grid pattern, while accommodating large modules which do not require cut-outs to be placed in the middle of the component.

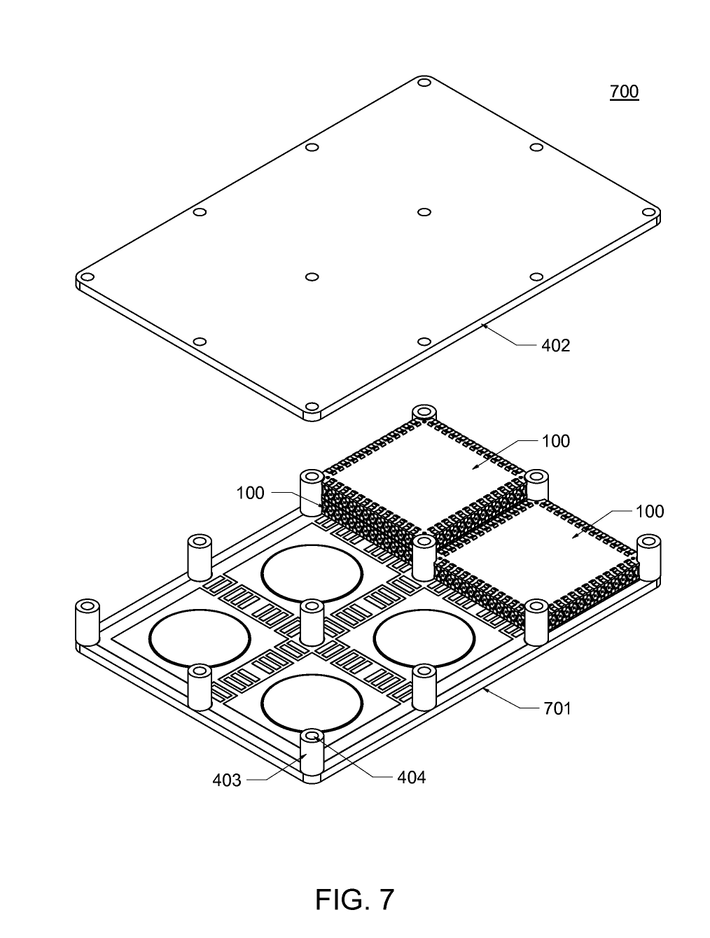

FIG. 7 is an isometric view of a multi-layered enclosure 700 adapted to house a plurality of layers of modules 100 in an exemplary embodiment of the invention. Enclosure 700 comprises a bottom plate 701, and a plurality of spacers 403 coupled to bottom plate 701. Each spacer 403 is twice the height of a module 100. A first layer of modules 100 may be placed horizontally on bottom plate 701. A second layer of modules 100 may be vertically stacked atop the first layer of modules 100. Stacked modules 100 are connected by outside contacts 109. A top plate 402 is placed above the second layer of modules 100 to secure modules 100 in a Z-direction. Multi-layered enclosure 700 allows six 1×1 modules 100 to be horizontally configured in an X-direction and a Y-direction of multi-layer enclosure 700. Additionally, multi-layered enclosure 700 allows for two layers of modules 100 to be stacked together, allowing up to twelve 1×1 modules 100 to be enclosed in multi-layered enclosure 700. However, any number of layers may be stacked, and any number of modules 100 may be horizontally placed on each layer depending on desired design criteria. Additionally, as described in FIG. 6, different sized modules having edges which are integer multiples of a base value may be horizontally and vertically configured in multi-layered enclosure 700.

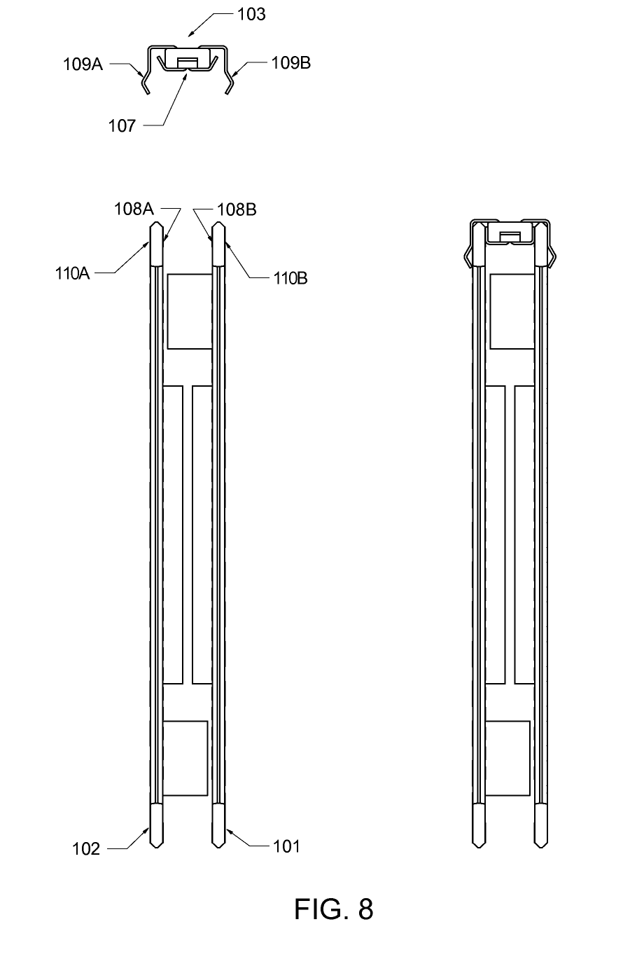

FIG. 8 is a side view of circuit boards 101 and 102 of module 100 being connected by inside contacts 107 of connector 103. Circuit board 102 is clamped between spring leaf outside contacts 109A and spring leaf inside contacts 107 of connector 103 causing electrical coupling of outside contacts 109A to outside contact pads 110A and electrical coupling of inside contacts 107 with inside contact pads 108A. Circuit board 101 is clamped between spring leaf outside contacts 109B and spring leaf inside contacts 107 of connector 103 causing electrical coupling of outside contacts 109B to contact pads 110B and electrical coupling of inside contacts 107 with contact pads 108A. Thus circuit board 101 is electrically coupled to circuit board 102 through contacts 107.

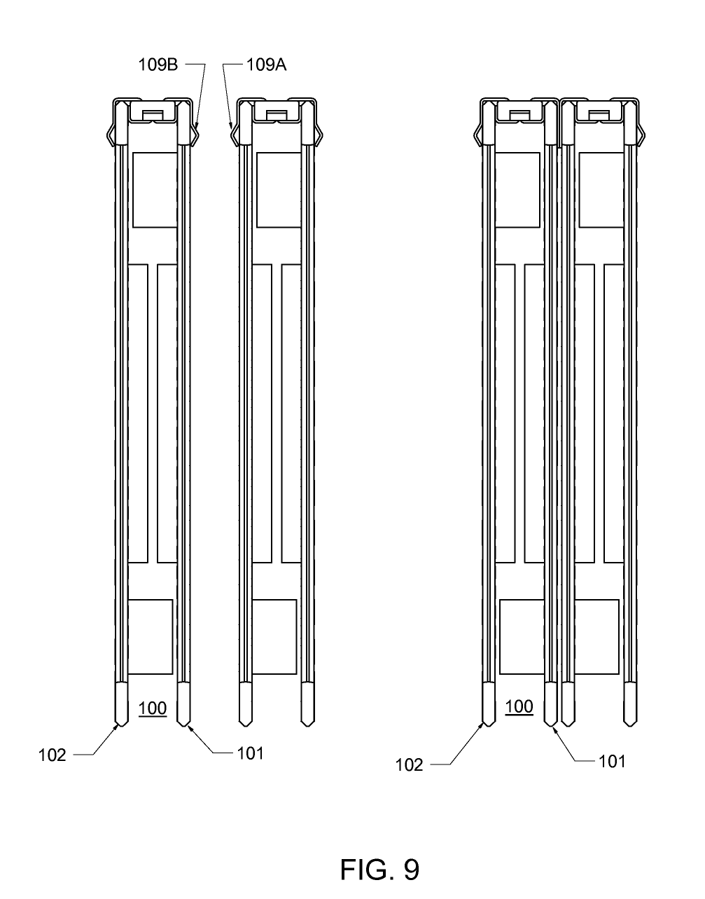

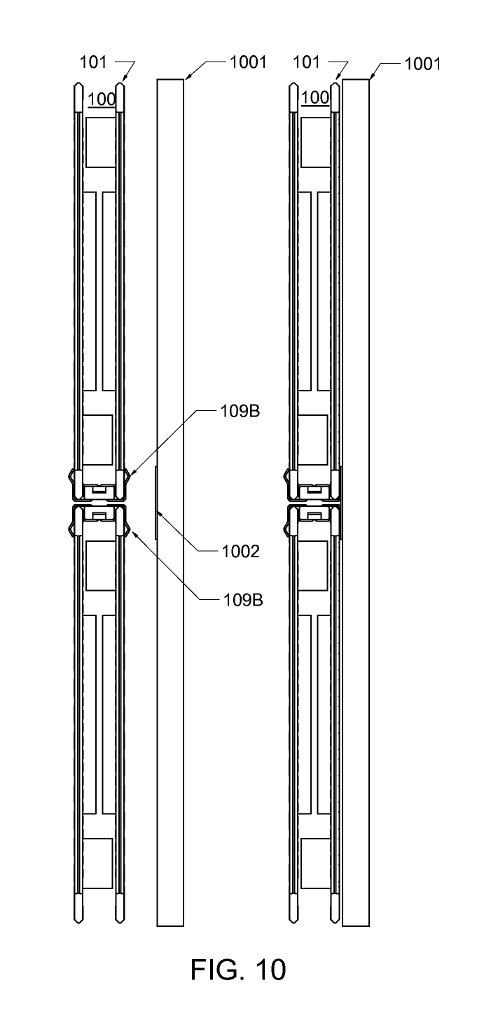

Module 100 is electrically coupled to other modules using outside spring leaf contacts. FIG. 9 is a side view of the connection between two stacked modules in an exemplary embodiment of the invention. More specifically, the left portion of FIG. 9 illustrates two modules prior to coupling, and the right portion of FIG. 9 illustrates two modules coupled together. FIG. 10 is a side view of the connection between two modules laid side-by-side in the same plane. More specifically, the left portion of FIG. 10 illustrates two modules prior to coupling, and the right portion of FIG. 10 illustrates two modules coupled together. The side-by-side coupling uses connector strips 1002 on enclosure base 1001 to couple with contacts 109B on the two modules.

As illustrated in FIGS. 1-3, module 100 comprises thirteen bottom spring leaf outside contacts 109B and thirteen top spring leaf outside contacts 109A. In the described embodiment, these thirteen pairs of connectors comprise a power contact, two ground contacts, two control signal contacts, and eight data signal contacts for transferring 8-bit data. However, any number of contacts and configurations may be used depending on desired design criteria.

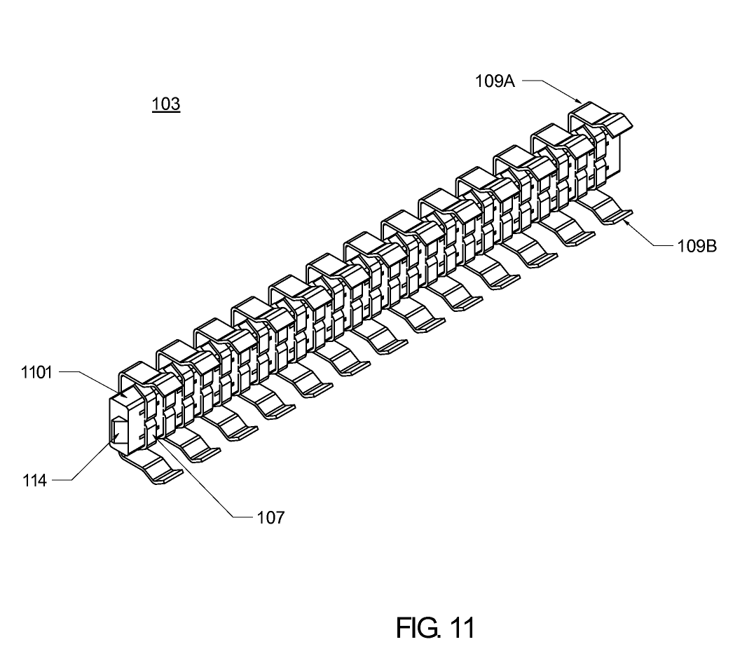

FIG. 11 is an isometric view of connector 103 showing inside spring leaf contacts 107 in an exemplary embodiment of the invention. Each inside contact matingly engages with inside contact pads on the circuit boards 101 and 102 of a module 100

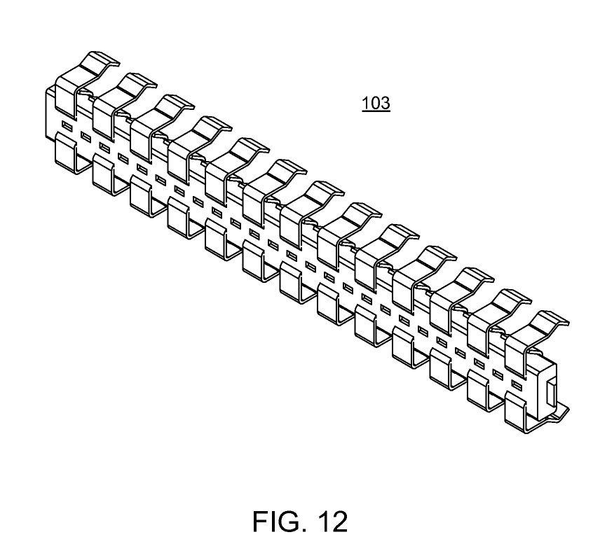

FIG. 12 is an isometric view of connector 103 showing outside spring leaf contacts 109A and 109B in an exemplary embodiment of the invention.

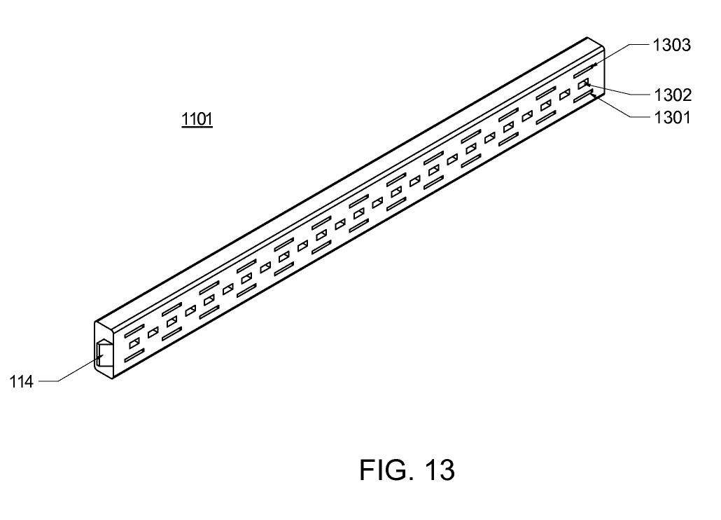

FIG. 13 is an isometric view of insulator material 1101 separating the top outside contacts, the bottom outside contacts, and the inside contacts in an exemplary embodiment of the invention. Insulator material 1101 may run substantially the length of top circuit board 102 (i.e., run the length of the edge between two cut-outs 111B). Insulator material 1101 has a plurality of slots 1301 adapted to electrically isolate each of the plurality of bottom outside contacts 109B. More specifically, insulator material 1101 may have thirteen slots 1301 to physically and electrically isolate each bottom outside contacts 109B. Additionally, insulator material 1101 has a plurality of slots 1303 adapted to electrically isolate each of the plurality of top outside contacts 109A. More specifically, insulator material 1101 may have thirteen slots 1303 to physically and electrically isolate each top outside contacts 109A. Additionally, insulator material 1101 has a plurality of slots 1302 adapted to electrically isolate each of the plurality of inside contacts 107. More specifically, insulator material 1101 may have twenty-five slots 1302 to physically and electrically isolate each inside contacts 107.

It may become necessary to couple an enclosure of modules 100, or one or more modules 100 to an external device. For example, if an enclosure comprises the components of a handheld computer, then it may become necessary to couple the modules of the enclosure to a printer, input device, network connection, external storage device, etc. An exemplary embodiment of the invention comprises provisions for coupling one or more modules 100 to an external device.

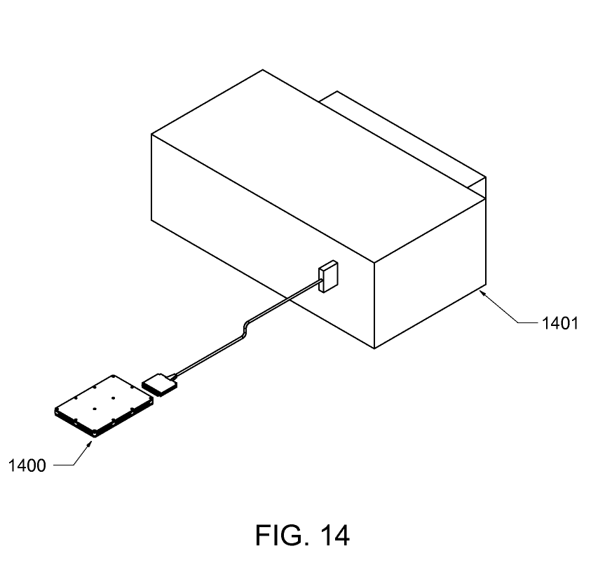

FIG. 14 is a view of a module enclosure 1400 connected to an external device 1401 in an exemplary embodiment of the invention. Module enclosure 1400 may house any number of modules 100, including a plurality of layers of modules 100. Module enclosure 1400 may also be one of a plurality of module enclosures which are vertically stacked atop one another. Module enclosure 1400 may further comprise a case for an electronic device, e.g., a handheld computer, mobile telephone, etc. External device 1401 may be a printer, external storage system, network connection, or any other type of external device connected to a computer, handheld computer or electronic device.

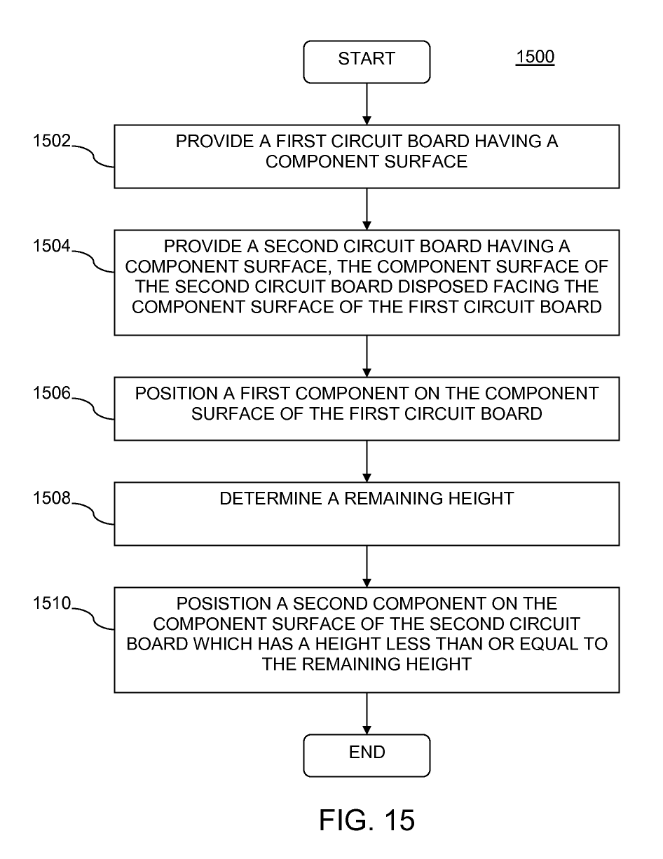

FIG. 15 is a flow chart of a method 1500 for forming a module in an exemplary embodiment of the invention. The steps of method 1500 will be described in reference to the module of FIGS. 1-3. The steps of method 1500 are not all inclusive, and may include other steps not shown for the sake of brevity.

Step 1502 comprises providing a first circuit board 101 having a component surface. Step 1504 comprises providing a second circuit board 102 having a component surface, the component surface of the second circuit board disposed facing the component surface of the first circuit board. Next, components on positioned on the component surface of the first circuit board and the component surface of the second circuit board to minimize un-utilized space between the first circuit board and the second circuit board. There is a first height between the first circuit board and the second circuit board. In step 1506, a first component is positioned on the component surface of the first circuit board. The first component has a second height which is less than the first height. In step 1508, a remaining height is determined based on the first height minus the second height. In step 1510, a second component is positioned on the first surface of the second circuit board, with the second component having a third height which is less than or equal to the remaining height. This results in a module with minimal un-utilized space, while providing a module which may be constructed of a uniform height as other modules.

Although specific embodiments were described herein, the scope of the invention is not limited to those specific embodiments. The scope of the invention is defined by the following claims and any equivalents therein.

I claim:

1. A system comprising at least one module, the at least one module comprising:
a first circuit board having a component surface,
characterized in that the module further comprises:
a second circuit board having a component surface, the component surface of the second circuit board disposed facing the component surface of the first circuit board; and
an apparatus adapted to physically and electrically couple the first circuit board and the second circuit board, and further adapted to matingly engage the module with a second module

2. The system of claim 1, wherein the apparatus for physically and electrically coupling the first circuit board and second circuit board comprises:
a plurality of top outside spring leaf contacts coupled to the outside contact pads of a top circuit board, each top outside spring leaf contact extending beyond the face of the top circuit board and adapted to matingly engage the module with a second module; and
a plurality of bottom outside spring leaf connectors coupled to the outside contact pads of a bottom circuit board, each bottom outside spring leaf contact extending beyond the face of the bottom circuit board and adapted to matingly engage the module with a third module; and
a plurality of inside spring leaf contacts coupled to the inside contact pads of the top circuit board, each inside spring leaf contact coupled to the inside contact pads of the bottom circuit board.

3. The system of claim 2, wherein the apparatus for physically and electrically coupling the first circuit board and second circuit board further comprises:
insulator material substantially a same length as an edge of the module, the insulator material having a plurality of slots adapted to electrically isolate each matingly engaged bottom outside spring leaf contact, a plurality of slots adapted to electrically isolate each matingly engaged top outside spring leaf connectors, and a plurality of slots adapted to electrically isolate each matingly engaged inside spring leaf connectors.

4. The system of claim 2, wherein the apparatus for physically and electrically coupling the first circuit board and second circuit board further comprises:
a plurality of inside spring leaf contacts adapted to matingly engage with inside contact pads along each edge of the first circuit board, each inside spring leaf contact adapted to matingly engage with inside contact pads along each edge of the second circuit board to electronically couple the first circuit board and the second circuit board.

5. The system of claim 4, wherein the plurality of top outside spring leaf connectors and bottom outside spring leaf connectors further comprises:
at least one power connectors;
at least one ground connectors;
at least one control signal connectors; and
at least one data signal connectors.

6. The system of claim 1 further comprising a plurality of modules.

7. The system of claim 6, wherein sizes of each edge of the first circuit board and the second circuit board are integer multiples of a base value.

8. The system of claim 7, wherein the first circuit board and the second circuit board further comprise means for securing the module in place in an enclosure housing the module.

9. The system of claim 8, wherein the means for securing the module in place in the enclosure housing the module further comprises:
a cut-out on each of the four corners of the first circuit board, and
a cut-out on each of the four corners of the second circuit board, the cut-outs on the first circuit board and the cut-outs on the second circuit board adapted to pass through a spacer in the enclosure housing the module to secure the module in place around the spacer.

10. The system of claim 9, wherein the enclosure comprises a plurality of spacers arranged in a grid pattern, each spacer being equally spaced apart in an X-direction and a Y-direction of the enclosure, with the base value equal to a distance between centers of two of the plurality of spacers.

11. A system comprising:
a plurality of modules, each module comprising:
a first circuit board having a component surface; and
a second circuit board having a component surface, the component surface of the second circuit board disposed facing the component surface of the first circuit board; and
an apparatus adapted to physically and electrically couple the first circuit board and the second circuit board and adapted to matingly engage the module with at least one of the other plurality of modules;
an enclosure adapted to house the plurality of modules; and
a plurality of spacers coupled to the enclosure, the plurality of spacers arranged in a grid pattern, each spacer being equally spaced apart in an X-direction and a Y-direction of the grid pattern; and
wherein sizes of each edge of the first circuit board and the second circuit board of each module are integer multiples of a base value, the base value equal to a distance between centers of two of the plurality of spacers.

12. The system of claim 11, wherein the apparatus for physically and electrically coupling the first circuit board and second circuit board comprises:
a plurality of top outside spring leaf contacts coupled to outside contact pads along each edge of the top circuit board, each top outside spring leaf contact extending beyond an outer face of the top circuit board and adapted to matingly engage the module with a second module; and
a plurality of bottom outside spring leaf contacts coupled with outside contact pads along each edge of the bottom circuit board, each bottom outside spring leaf contact extending beyond an outer face of the bottom circuit board and adapted to matingly engage the module with a third module; and
a plurality of inside spring leaf contacts coupled to inside contact pads on the top circuit board and inside contact pads on the bottom circuit board to electronically couple the first circuit board and the second circuit board.

13. The system of claim 11, wherein the apparatus for physically and electrically coupling the first circuit board and second circuit board further comprises:
a plurality of layers of modules housed in the enclosure, wherein at least one layer of modules is stacked atop a lower layer of modules.

14. A method for forming a module, the method comprising:
providing a first circuit board having a first surface,
the method further characterized by:
providing a second circuit board having a first surface, the first surface of the second circuit board disposed facing the first surface of the first circuit board; and
positioning components on the first surface of the first circuit board and the first surface of the second circuit board to minimize un-utilized space between the first circuit board and the second circuit board.

15. The method of claim 14, wherein there is a first height between the first circuit board and the second circuit board, and positioning components further comprises:
positioning a first component on the first surface of the first circuit board, the first component having a second height less than the first height;
determining a remaining height based on the first height minus the second height; and
positioning a second component on the first surface of the second circuit board, the second component having a third height which is less than or equal to the remaining height.

16. Modules with footprints that are restricted to closed shapes that can be constructed by arranging segments of a unit length end-to-end such that all segments are either parallel or perpendicular to one-another and where said modules have a plurality of electrical contacts centered along the edge of at least one of said segments such that a plurality of modules can be electrically connected to one-another by way of said contacts when said plurality of modules are stacked atop one-another.

17. The modules of claim 16 where said modules are also laid side by side of one-another and connected by an apparatus that contains conductive strips where said apparatus is oriented parallel to said modules in order to mate with said perimeter contacts of both modules in order to effect electrical connection between the contacts of said stacked modules.
